(19) United States
(12) Patent Application Publication
(10) Pub. No.: US 2008/0093109 A1
(43) Pub. Date: Apr. 24, 2008

(54) Substrate with surface finished structure and method for making the same

(75) Inventors: Shih-Ping Hsu, Hsin-feng (TW); Ya-Lun Yen, Hsin-feng (TW)

Correspondence Address: BACON & THOMAS, PLLC, 625 SLATERS LANE, FOURTH FLOOR, ALEXANDRIA, VA, 22314, US

(73) Assignee: Phoenix Precision Technology Corporation, Hsinchu (TW)

(21) Appl. No.: 11/583,084

(22) Filed: Oct. 19, 2006

(51) Int. Cl. H05K 1/00

(52) U.S. Cl. 174/250

(57) ABSTRACT

A substrate with surface finished structure and a method for manufacturing the same are disclosed. The method comprises: forming a circuit layer and a solder mask on the surface of the substrate in sequence, wherein a plurality of openings are formed in the solder mask to expose the portion of the circuit layer to be electrical contact pads which having at least a wire bonding pad and a plurality of solder pads; and forming a Ni/Au layer on the surface of the wire bonding pad and a chemical gold layer on the surface of the solder pads. Therefore, the disclosed structure can prevent the electrical contact pads from oxidation for a long time.

### BACKGROUND OF THE INVENTION

1. Field of the Invention

The present invention relates to a surface with surface finished structure and a method for making the same and, more particularly, to a surface with surface finished structure and a method for manufacturing the same that apply to a chemical gold layer is formed on the surface of the electrical contact pads.

2. Description of Related Art

Generally speaking, to prevent further oxidation of the electrical pads on the substrate, the surface of the electrical pads are surface-treated by coating a layer of organic solderability preservatives (i.e. OSP) for inhibiting oxidation and extending the waiting time for surface finished process. If the substrate is not subject to the surface treatment illustrated above, the copper in the electrical contact pads will be easily oxidized to produce a metal oxide layer after a period of time. As a result, for the molten solders to stick on, the surface of the metal oxide layer is like a non-stick pan. In other words, the molten solders can't be mounted. Thus, electronic parts or wires cannot be bond on the substrate in the situation described above. Besides, it can affect the quality of the telecommunication by transmitting signals from exterior electronic element to the substrate.

If the substrate is protected by an OSP coating, the protection of copper by a transparent film on the surface of the electrical contact pads on the substrate can be achieved. Furthermore, the dual purposes of copper surface protection and the preservation of solderability can be achieved. However, if the time for waiting subsequent process is extended, the OSP still volatilizes to lose the protection for copper surface. Hence, it is not an ideal protection for copper electrical pads.

On the other hand, some researchers suggest metalizing the electrical pads by forming a tin layer thereon. The method for surface-treating the substrate known in the art can be seen in FIG. 1A to FIG. 1C. First, referring to FIG. 1A, a substrate 10 is provided, wherein a copper foil 11, a circuit layer 12 and a solder mask 13 are formed on the surface of the substrate 10 in sequence, and a plurality of openings are formed in the solder mask 13 to expose the portion of the circuit layer 13 therebeneath for being electrical contact pads 14. The electrical contact pads 14 comprise a plurality of solder pads 14a and at least a wire bonding pad 14b. Then, a Ni/Au layer 15 is formed on the surface of the wire bonding pad 1 4b (a Ni layer is formed first, and then an Au layer is covered thereon). Then, as shown in FIG. 1B, an OSP layer 16 is formed on the surface of the solder pad 14a. Finally, as shown in FIG. 1C, a solder material 17 is formed in the opening of the solder pad 14a by screen printing, and then by way of surface mounted technology (SMT), the passive component (not shown) is mounted to the surface of the substrate 10. The process of mounted the passive component (not shown), the OSP layer 16 is evaporated as a result of high temperature. Herein, the OSP layer 16 can achieve the dual purposes of the protection of copper surface and solderability.

However, when the surface of the solder pads with smaller and denser pitch is printed with solder paste by screen printing, it's difficult to align. Moreover, the OSP layer can't be stored for a long time even though the above-mentioned metal surface process of the electrical contact pads on the surface of the substrate is achieved. So, it will have the effectiveness to the proceeding process and quality of the substrate.

Therefore, it is desirable to provide an improved speech recognition method to mitigate and/or obviate the aforementioned problems.

### SUMMARY OF THE INVENTION

The present invention relates to a substrate with surface finished structure, which comprises a substrate and a chemical gold layer. Where the substrate having a circuit layer and solder mask are formed on the surface of the substrate in sequence, and a plurality of openings are formed in the solder mask to expose the portion of the circuit layer therebeneath to be electrical contact pads, which have at least a wire bonding pad and solder pads. A Ni/Au layer are formed on the surface of the at least one wire bonding pad, and a chemical gold layer are formed on the surface of the solder pads.

Therefore, the substrate with surface finished structure of the present invention, which can prevent the solder pads from oxidation for a long time, by the protection of the chemical gold layer.

Besides, a chemical gold layer is also formed on surface of the above-mentioned Ni/Au layer.

In additional, the solder mask can be one selected from the group consisting of green paints and black paints.

Moreover, the substrate can be either single-layer circuit board or multi-layer circuit board.

The present invention relates to a method for manufacturing a substrate with surface finished structure, which comprises the following steps:

(A) providing a substrate having a circuit layer and a solder mask formed on the surface of the substrate, and forming a plurality of openings in the solder mask to expose the portion of the circuit layer therebeneath to be electrical contact pads which having at least a wire bonding pad and solder pads;

(B) forming a Ni/Au layer on the surface of the at least one wire bonding pad; and

(C) forming a chemical gold layer in the openings.

Besides, the method of the present invention, wherein further comprising a step of (B1) after the step of (B): forming a resist layer on the opening and the surface of the solder mask, and forming a plurality of resist layer openings in the resist layer to expose the surface of the solder pads therebeneath.

Moreover, the method of the present invention, wherein further comprising a step of (C1) after the step of (C): removing the resist layer.

Further, the method of the present invention, wherein the method of forming the chemical gold layer in step (C) is one selected from the group consisting of sputtering, vapor deposition, physical deposition, and chemical deposition.

Besides, the method of the present invention, wherein the method of forming the resist layer in step (B1) is one selected from the group consisting of printing, spin coating, press bonding, and laminating.

Therefore, the method of the present invention, wherein the method of forming the resist layer openings in step (B1) are exposure and development, or the like.

Moreover, the method as claimed in claim 6, wherein the method of removing the resist layer is either peeling or stripping.

Other objects, advantages, and novel features of the invention will become more apparent from the following detailed description when taken in conjunction with the accompanying drawings.

### BRIEF DESCRIPTION OF THE DRAWINGS

FIG. 1A to FIG. 1C are cross-sections of a prior art method for manufacturing the substrate with surface finished structure;

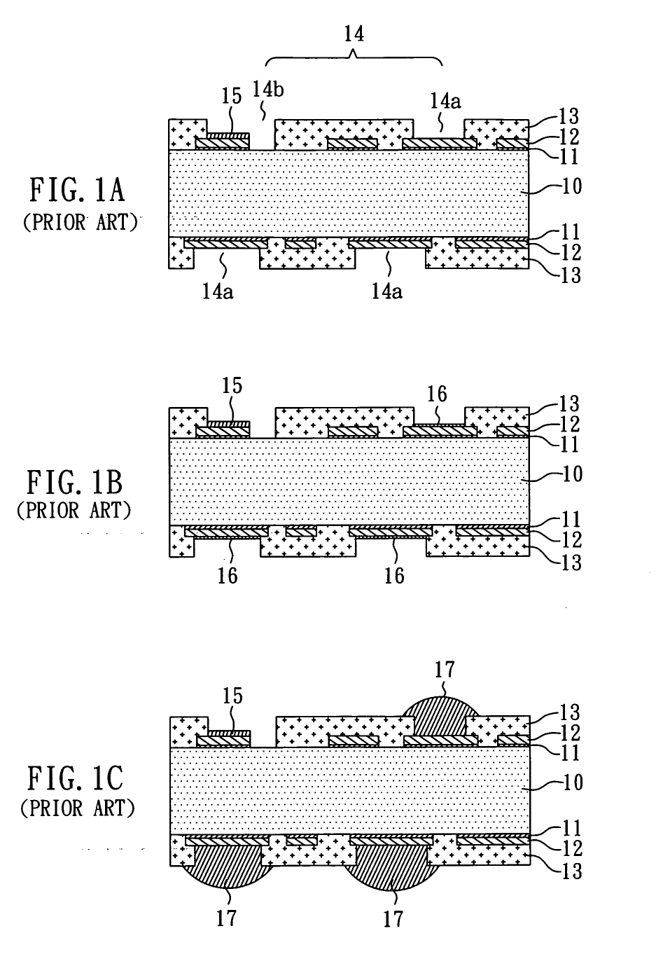

FIG. 2A to 2B are cross-sections of a method for manufacturing the substrate with surface finished structure of a preferred embodiment of the present invention; and

FIG. 3A to 3D are cross-sections of a method for manufacturing the substrate with surface finished structure of another preferred embodiment of the present invention.

### DETAILED DESCRIPTION OF THE PREFERRED EMBODIMENT

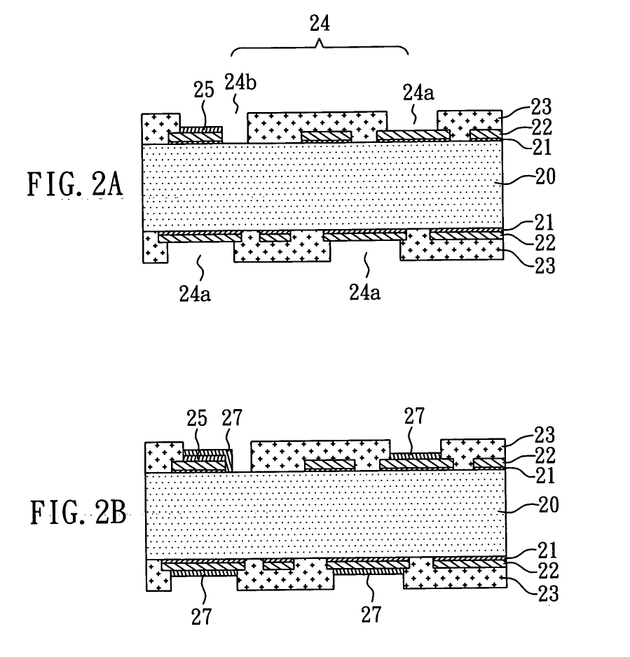

Referring to FIGS. 2A to 2B, which are schematic cross-section illustrations of the substrate with surface finished structure of a preferred embodiment of the present invention. First, as shown in FIG. 2A, a substrate 20 is provided, which can be a single-layer or a multi-layer finished the preceding process circuit board. Besides, a seed layer 21, a circuit layer 22, and a solder mask 23 for isolation and protection are formed on the upper and lower surface of the substrate 20, and a plurality of openings are formed in the solder mask 23 by exposure and development to expose the portion of the circuit layer 22 therebeneath to be electrical contact pads 24, wherein the electrical contact pads 24 comprise at least a wire bonding pad 24b and solder pads 24a (step A). Then, a Ni/Au layer 25 is formed on the surface of the wire bonding pad 24b (a Ni layer is formed first, and then an Au layer is covered thereon) (step B).

After that, as shown in FIG. 2B, a chemical gold layer 27 is coated on the surface of the solder pads 24a and the Ni/Au layer 25 on the wire bonding pad 24b by chemical deposition (step C).

Thus, the substrate 20 with surface finished structure made of the example, the surface of the solder pads 24a and the Ni/Au layer 25 on the wire bonding pad 24b have a chemical gold layer 27. The solder pads 24a will not be oxidized for a long time by the protection of the chemical gold layer 27.

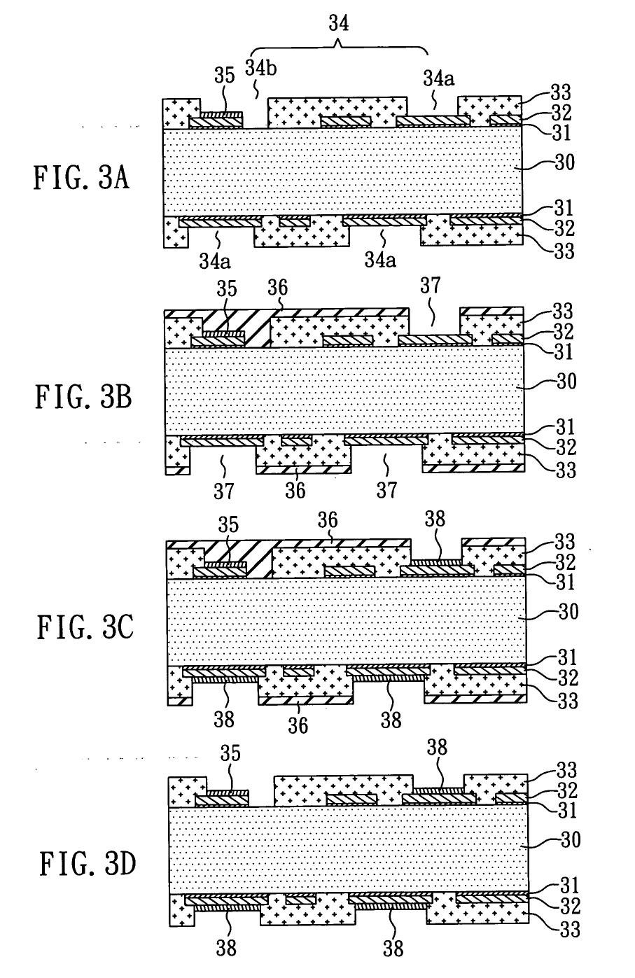

Then, referring to FIGS. 3A to 3D, which are schematic cross-section illustrations of the substrate with surface finished structure of a second preferred embodiment of the present invention. The step (A) of the second example and the step (A) of the first example are the same. First, as shown in FIG. 3A, a substrate 30 is provided, which can be a single-layer or a multi-layer finished the preceding process circuit board. Besides, a seed layer 31, a circuit layer 32, and a solder mask 33 are formed on the upper and lower surface of the substrate 30, and a plurality of openings are formed in the solder mask 33 to expose the portion of the circuit layer 32 therebeneath to be electrical contact pads 34, wherein the electrical contact pads 34 comprise at least a wire bonding pad 34b and solder pads 34a (step A). Then, a Ni/Au layer 35 is formed on the surface of the wire bonding pad 34b (a Ni layer is formed first, and then an Au layer is covered thereon) (step B).

Then, as shown FIG. 3B, a resist layer 36 of photosensitive polymer material is formed on the openings and the surface of the solder mask 33, and a plurality of the resist layer openings are formed in the resist layer 36 by exposure and development to expose the surface of the solder pads 34a therebeneath (step B1). Then, as shown FIG. 3C, a chemical gold layer 38 is coated on the surface of the solder pads 34a by chemical deposition (step C). Finally, as shown in FIG. 3D, the resist layer 36 is removed to expose the Ni/Au layer 35 on the wire bonding pad 34b and the solder mask 35 therebeneath (step C1).

The difference between the substrate 30 with surface finished structure of the second example and the first example is the chemical gold layer 38 only formed on the surface of the solder pads 34a in the second example, however, the chemical gold layer 27 is formed on the surface of the solder pads 24a and the Ni/Au layer 25 on the wire bonding pad 24b at the same time in the first example. The surface of the solder pads 34a of the second example are protected by the chemical gold layer 38, and also have the effectiveness as the first example. That is, the surface of the solder pads 34a of the second example does not oxidation easily for a long time.

Although the present invention has been explained in relation to its preferred embodiment, it is to be understood that many other possible modifications and variations can be made without departing from the scope of the invention as hereinafter claimed.

1. A substrate with surface finished process structure, comprising:
a substrate having a circuit layer, solder mask, and a plurality of openings, wherein the solder mask is formed on the surface of the substrate in sequence, the openings are formed in the solder mask to expose the portion of the circuit layer therebeneath to be electrical contact pads, and the electrical pads have at least a wire bonding pad and solder bumping pads;
a Ni/Au layer formed on the surface of the at least one wire bonding pad; and a chemical gold layer formed on the surface of the solder bumping pads.

2. The structure as claimed in claim 1, wherein the chemical gold layer is formed on the surface of the Ni/Au layer.

3. The structure as claimed in claim 1, wherein the substrate is either single-layer circuit board or multi-layer circuit board.

4. The structure as claimed in claim 1, wherein solder mask is either green paints or black paints.

5. A method for manufacturing a substrate with surface process finished structure, comprising the following steps:
(A) providing a substrate having a circuit layer, a solder mask, and a plurality of openings, wherein the solder mask is formed on the surface of the substrate, the openings are formed in the solder mask to expose the portion of the circuit layer therebeneath to be electrical contact pads, and
the electrical pads have at least a wire bonding pad and solder bumping pads;
(B) forming a Ni/Au layer on the surface of the at least one wire bonding pad; and
(C) forming a chemical gold layer in the openings.

6. The method as claimed in claim 5, further comprising a step of (B1): forming a resist layer on the openings and the surface of the solder mask, and forming a plurality of resist layer openings in the resist layer to expose the surface of the solder bumping pads therebeneath, wherein the step of (B1) is performed after the step of (B) and before the step of (c).

7. The method as claimed in claim 6, further comprising a step of (C1): removing the resist layer, wherein the step of (C1) is performed after the step of (c).

8. The method as claimed in claim 5, wherein the solder mask of the step (A) is either green paints, or black paints.

9. The method as claimed in claim 5, wherein the chemical gold layer in step (c) is formed by sputtering, vapor deposition, physical deposition, or chemical deposition.

10. The method as claimed in claim 6, wherein the resist layer in step (B1) is formed by printing, spin coating, press bonding, or laminating.

11. The method as claimed in claim 6, wherein the formation of the resist layer openings in step (B1) are achieved by exposure and development.

12. The method as claimed in claim 7, wherein the removing of the resist layer is achieved by peeling, or stripping.
